(19) United States
(12) Patent Application Publication
(10) Pub. No.: US 2011/0140749 A1
(43) Pub. Date: Jun. 16, 2011

(54) INPUT DATA RECOVERY CIRCUIT FOR ASYNCHRONOUS SERIAL DATA TRANSMISSION

(76) Inventor: Chin-Cheng HUANG, Taipei County (TW)

(21) Appl. No.: 12/638,537

(22) Filed: Dec. 15, 2009

(51) Int. Cl. H03K 5/01

(52) U.S. Cl. 327/166

(57) ABSTRACT

An input data recovery circuit is applied for asynchronous serial data transmission such as USB, SATA, or PCI-E. The input data recovery circuit includes two-tier switches controlled by the switching state of input data signal and pulse signals. The input data recovery circuit further includes pulse generator for producing pulse signals to trigger the input data signal and correctly recover the input data signal. The input data recovery circuit can be applied to equipment with high speed protocol because accumulated error between data sending end and data receiving end can be prevented.

### BACKGROUND OF THE INVENTION

1. Field of the Invention

The present invention relates to an input-signal recovery circuit, especially to an input-signal recovery circuit recovering data signal by input data signal and asynchronous serial bus data reception system.

2. Description of Prior Art

The most serous problem for a data reception system using asynchronous serial bus is the frequency mismatch between a data transmitting end and a data receiving end. More particularly the data transmitting end and the data receiving end do not have common signal clock like that of the asynchronous serial bus, and error is accumulated when frequency mismatch is present therebetween.

FIG. 1 shows a related art data reception system using asynchronous serial bus, which is filed by the same applicant in U.S. with application Ser. No. 12/393,737. As shown in this figure, the data reception system uses a pulse generator 120 to receive an input data signal Dr and then sends first pulse signals Vp1 to nth pulse signals Vpn to a switch set 130. The on/off of the switch set 130 is controlled by the switching state of the input data signal Dr and falling edge of the pulse signal Vp.

FIG. 2 shows the flowchart for the operation of the switch set 130 shown in FIG. 1, this flowchart ensures only one switch in the switch set 130 is turned on at one time, while other switches are turned off. The on/off of the switches is controlled by the switching state of the input data signal Dr and falling edge of the pulse signal Vp.

FIG. 3a shows the circuit diagram for the data switch detector 110 in FIG. 1. FIG. 3b shows the truth table for XOR gate 112. FIG. 3c shows the waveforms for the data switch detector 110. The input data signal Dr is delayed by a half-period buffer 111, which outputs an internal signal Va, the internal signal Va and the input data signal Dr are sent to input ends of the XOR gate 112 to generate an output signal Vdsd. More particularly, the output signal Vdsd with half-period duration is generated when data switching (namely, logic change) between binary 1 and binary 0 is present in the input data signal Dr.

FIG. 4a shows the circuit diagram of the first logic circuit 120 in the pulse generator shown in FIG. 1. FIG. 4b shows the waveforms for the first logic circuit 120. Similar to the data switch detector 110, the input data signal Dr is delayed by a half-period buffer 121 to generate an internal signal V1b. The internal signal V1b is delayed by another half-period buffer 122 to generate another internal signal V1c. The internal signals V1b and V1c are sent to input ends of an XOR gate 123 to generate a first pulse signal Vp1. In other word, after half-period delay, first pulse signal Vp1 with half-period pulse width (in terms of logic high level) is generated when data switching between binary 1 and binary 0 is present in the input data signal Dr.

Similarly, the internal signal V1c output by the half-period buffer 122 is used as input signal for the logic circuit of next stage. In this manner, the second pulse signal Vp2 to the n-th pulse signal Vpn can be generated.

FIG. 5 shows waveforms for explaining the operation of the logic circuit with first pulse signal Vp1 to the fourth pulse signal Vp4, where the pulse signals Vp1˜Vp4 are delayed each other by one period. The control for the switches SW1˜SWn in the switch set 130 can be manifested with reference to this figure and also to FIG. 2. It should noted that only four switches SW1˜SW4 are shown in FIG. 5 and the shaded regions indicate logic 1 level. A final pulse signal Vp can be obtained to trigger the flip-flop 140, which also receives the input data signal Dr, thus obtaining an output data signal Dout.

FIG. 6 is another viewpoint for FIG. 5 where the switch conduction state and pulse signal are combined for better demonstration. The pulse signals Vp1˜Vp4 indicate the input pulse signal to the switches SW1˜SW4, respectively. Taking the waveform for SW1 (&Vp1) as example, the arrow “↑” indicates a rising edge for the first pulse signal Vp1. The number in the waveform means the ordinal number for the input data signal Dr. Similarly, Vp2˜Vp4 indicate the second to fourth pulse signals in SW2(&Vp2)˜SW4(&Vp4).

To fetch the correct signal, the rising edge of the final pulse signal Vp should be within the input data signal Dr. Provided that the max bit number for successive signal with unchanged logic state is n, and the rule for fetching the correct signal is

(n−1)·T<(n−½)·(2·Td05)<n·T

→(n−1)·T<(n−½)·(T+ΔT)<n·T

→(−½)·T/(n−½)<ΔT<(½)·T/(n−½)

Where ΔT=2. Td05−T, and Td05 is the delay time for the half-period buffer and T is the period for the input data.

This rule imposes a limit for ΔT (namely, the difference between two times of the delay time for the half-period buffer and the period for the input data). More particularly, ΔT cannot be too large to cause fetching error for the input data signal Dr. Therefore, ΔT is an important design parameter for the present invention.

Moreover, another parameter Tf2s (the delay time of pulse falling-edge to switch turn-on/turn-off) is also important design parameter for the present invention. If ΔT>0 and Tf2s is too short, as shown in FIG. 7, after the falling edge of the first switch SW1, the rising edge of the second switch SW2 will fetch the tail of the second pulse signal Vp2, which is corresponding to the previous data (namely, the input data signal Dr is logic high). As a result, an additional pulse (unwanted pulse) is generated and data is erroneously fetched. Therefore, the related art circuit should obey the rule of Tf2s being larger than ΔT.

### SUMMARY OF THE INVENTION

It is an object of the present invention to provide an input data recovery circuit is applied for asynchronous serial data transmission, the input data recovery circuit employs two tiers of switches to overcome the problem occurred in the related art.

Accordingly, the input data recovery circuit according to the present invention provides two sub switch sets and a main switch set in the pulse generator. The switches in the two sub switch sets and the main switch set are respectively controlled by the data switching state and the triggering of pulse signals, thus correctly outputting the pulse signals from the pulse generator.

Therefore, the input data recovery circuit according to the present invention can overcome the limitation Tf2s (the delay time of pulse falling-edge to switch turn-on/turn-off) being larger than ΔT, and the new limitation is Tf2s>0. Because no negative delay time is present in practical circuit, there will be no additional pulse in the input data recovery circuit according to the present invention.

### BRIEF DESCRIPTION OF DRAWING

The features of the invention believed to be novel are set forth with particularity in the appended claims. The invention itself however may be best understood by reference to the following detailed description of the invention, which describes certain exemplary embodiments of the invention, taken in conjunction with the accompanying drawings in which:

FIG. 1 shows a related art data reception system using asynchronous serial bus.

FIG. 2 shows the flowchart for the operation of the switch set shown in FIG. 1.

FIG. 3a shows the circuit diagram for the data switch detector in FIG. 1.

FIG. 3b shows the truth table for XOR gate.

FIG. 3c shows the waveforms for the data switch detector.

FIG. 4a shows the circuit diagram of the first logic circuit in the pulse generator shown in FIG. 1.

FIG. 4b shows the waveforms for the first logic circuit.

FIG. 5 shows waveforms for explaining the operation of the logic circuit.

FIG. 6 is another viewpoint for FIG. 5 where the switch conduction state and pulse signal are combined for better demonstration.

FIG. 7 depicts the unwanted pulse if ΔT>0 and Tf2s is too short.

FIG. 8 shows the circuit diagram of the input data recovery circuit according to a preferred embodiment of the present invention.

FIG. 9a shows the flowchart for the sub switch sets.

FIG. 9b shows the flowchart for the main switch set.

FIG. 10a shows the circuit diagram for the first set of logic circuit.

FIG. 10b shows the truth table for the first set of logic circuit.

FIG. 10c shows the waveforms for the first set of logic circuit.

FIG. 11 shows the waveforms of the pulse signals and the switching status of switches.

FIG. 12 depicts the waveforms for the condition with that ΔT>0 and Tf2s is too short.

FIG. 13a shows the flowchart for the switch control according to another embodiment of the present invention.

FIG. 13b shows the switching control of the main switch set according to another preferred embodiment of the present invention.

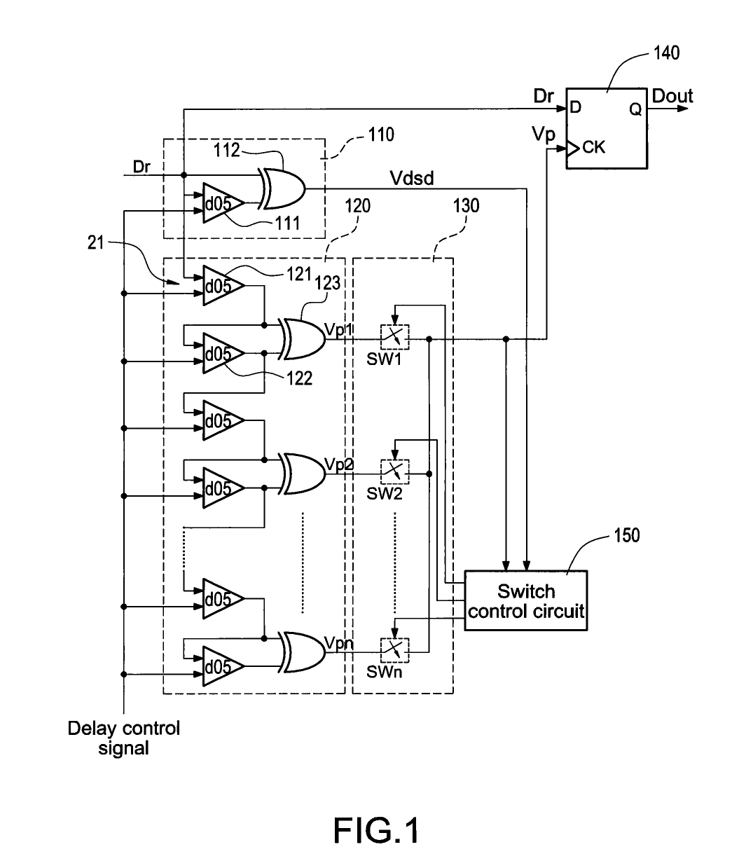

### DETAILED DESCRIPTION OF THE INVENTION

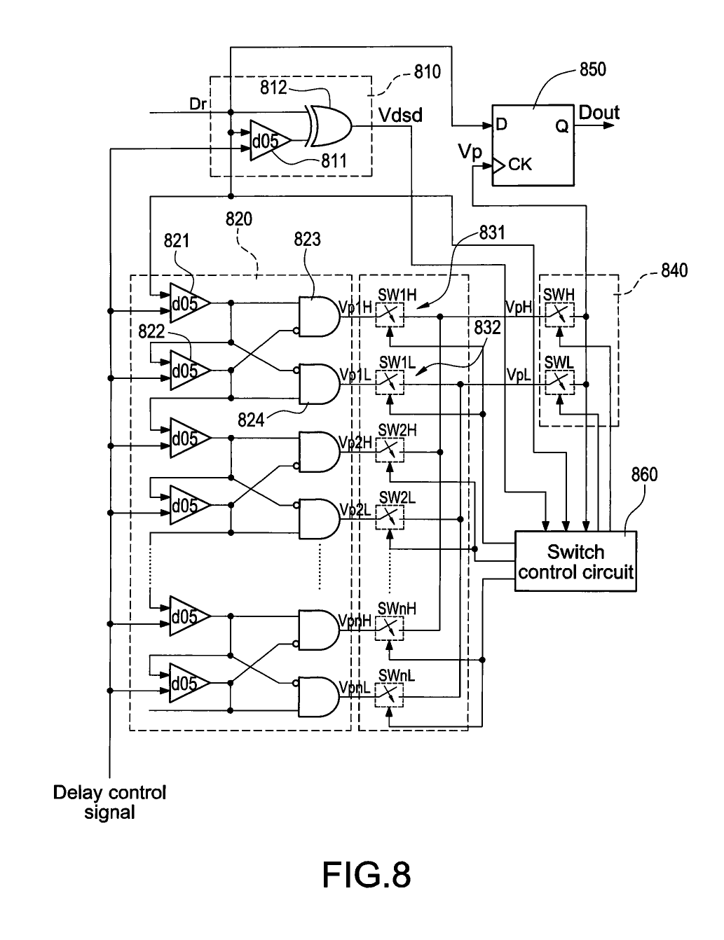

FIG. 8 shows the circuit diagram of the input data recovery circuit according to a preferred embodiment of the present invention. The input data recovery circuit according to the present invention comprises two input ends and one output end, where the two input ends receive an input data signal Dr and a delay control signal, respectively, and the output end outputs a data output signal Dout. The input data recovery circuit according to the present invention further comprises a data switch detector 810, a pulse generator 820, a high-pass sub switch set 831, a low-pass sub switch set 832, a main switch set 840, and a switch control circuit 860. The two input ends of the pulse generator 820 receive the input data signal Dr and the delay control signal, respectively. The pulse generator 820 then outputs a plurality of high pulse signals Vp1H˜VpnH and a plurality of low pulse signals Vp1L˜VpnL to the corresponding high-pass sub switches SW1H˜SWnH and the corresponding low-pass sub switches SW1L˜SWnL in the sub switch sets 831 and 832, respectively. The data switch detector 810 senses the switching state of the input data signal Dr and controls the on/off of the switches in the sub switch sets 831 and 832 through the switch control circuit 860 and the triggering of the pulse signals.

In the high-pass sub switch set 831, all output ends of the high-pass sub switches SW1H˜SWnH are commonly connected to a high-pass output end, where the high-pass output end is electrically connected to a high-pass input end in a high-pass main switch SWH in the main switch set 840. In the high-pass sub switch set 831, all output ends of the low-pass sub switches SW1L˜SWnL are commonly connected to a low-pass output end, where the low-pass output end is electrically connected to a low-pass input end in a low-pass main switch SWL in the main switch set 840. When the switches in the sub switch sets 831 and 832 are turned on sequentially, the pulse signals Vp1H˜VpnH, Vp1L˜VpnL are output to the main switch set 840 to function as an input high-pass pulse signal VpH and an input low-pass pulse signal VpL, respectively. The main switch set 840 outputs a final pulse signal Vp, which depends on the conduction state of the main switch set 840.

The final pulse signal Vp output by the main switch set 840 is sent to the clock input end of the flip-flop 850 to trigger the input data signal Dr input to the flip-flop 850, thus correctly outputting the data output signal Dout. Moreover, the final pulse signal Vp output by the main switch set 840 is also sent to the switch control circuit 860 to control the on/off of the switches in the sub switch sets 831 and 832.

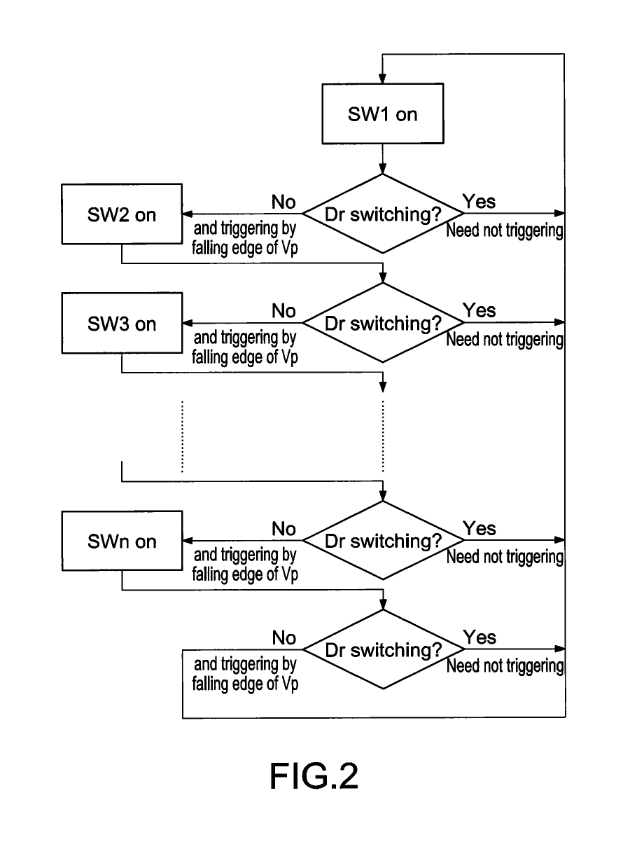

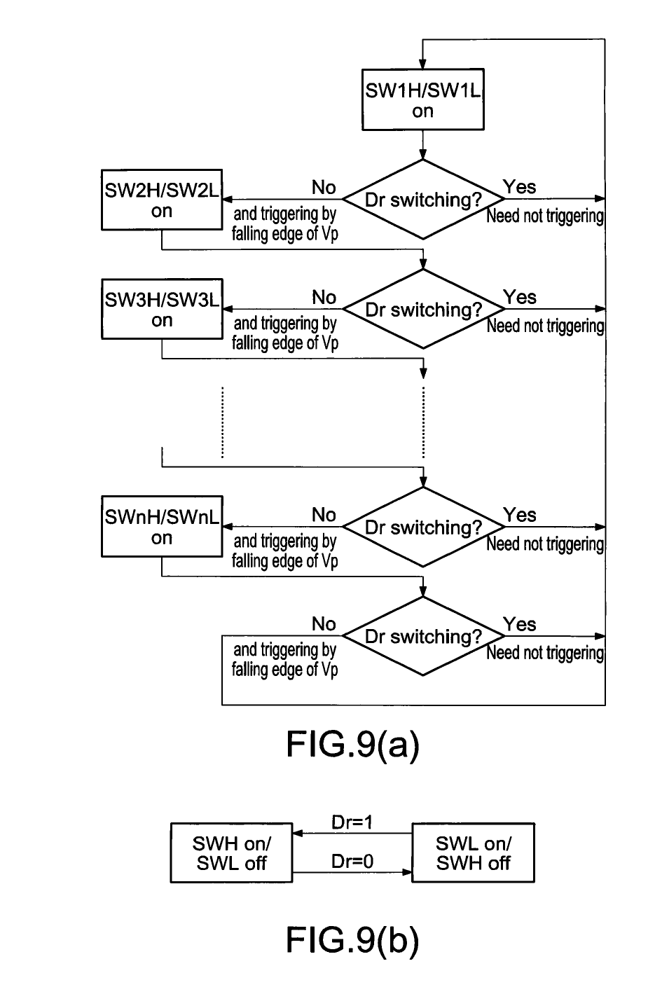

The sub switch sets 831 and 832 and the main switch set 840 are controlled with reference to the flowchart shown in FIG. 9a and the schematic diagram shown in FIG. 9b. As shown in FIG. 9a, the switching of the sub switch sets 831 and 832 is similar to that shown in FIG. 2 except that the corresponding sub switches in the sub switch sets 831 and 832 are turned on simultaneously. When a logic change is present in the input data signal Dr (namely from logic 0 to logic 1 and vice versa), the flow is back to the state where the first sub switches SW1H (SW1L) are on, and the triggering of the final pulse signal Vp is not necessary. When the input data signal Dr maintains the same logic state (namely, no logic high/low change), the second sub switches SW2H (SW2L), the third sub switches SW3H (SW3L), . . . , the n-th sub switches SWnH (SWnL) are sequentially turned on by the triggering of the falling edge of the final pulse signal Vp.

FIG. 9b shows the switching of the switches in the main switch set 840, where only one of the switches is on for the same time (namely, either the high-pass main switch SWH is on or the low-pass main switch is on). When the input data signal Dr is logic high, the high-pass main switch SWH is on; when the input data signal Dr is logic low, the low-pass main switch SWL is on. In other word, the on/off state of the main switch set 840 is directly controlled by the logic state of the input data signal Dr.

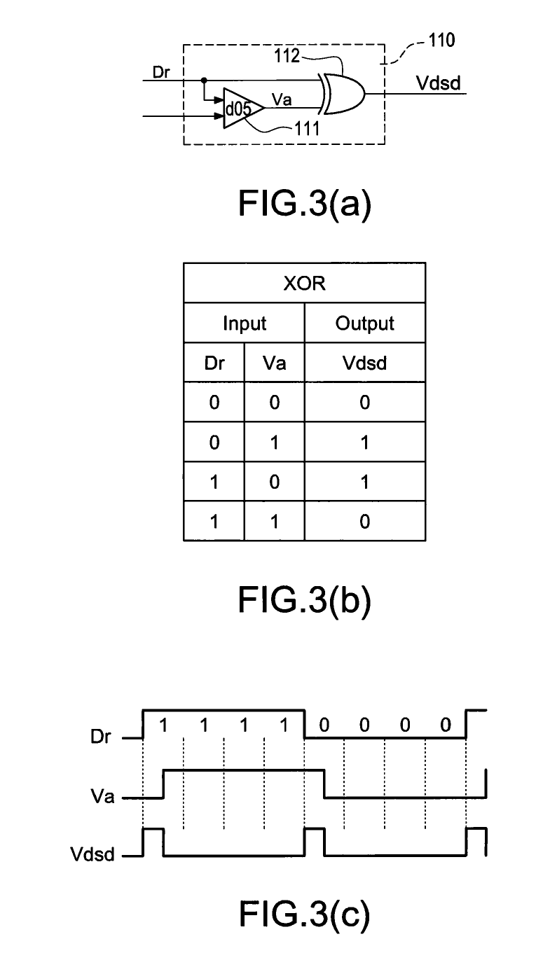

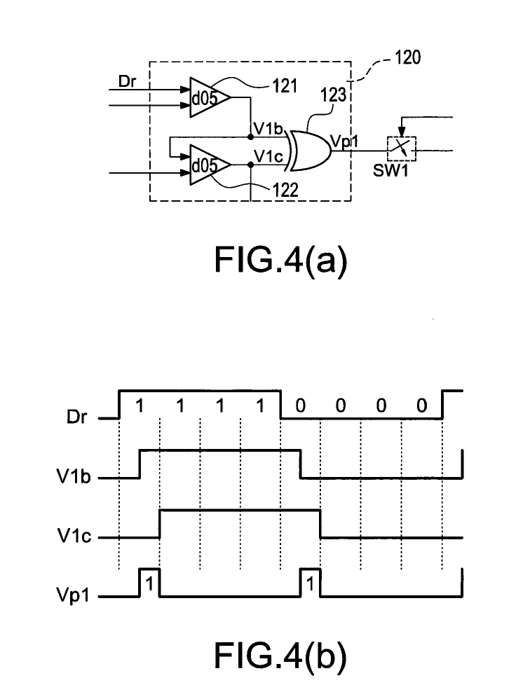

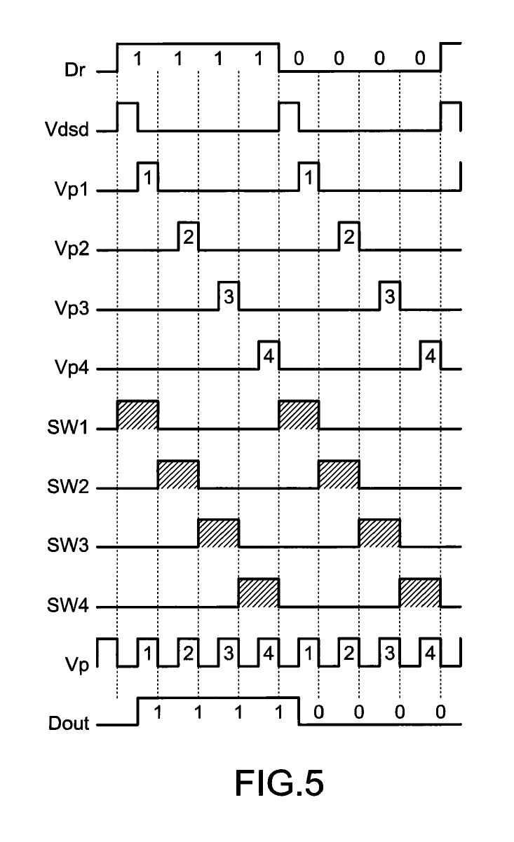

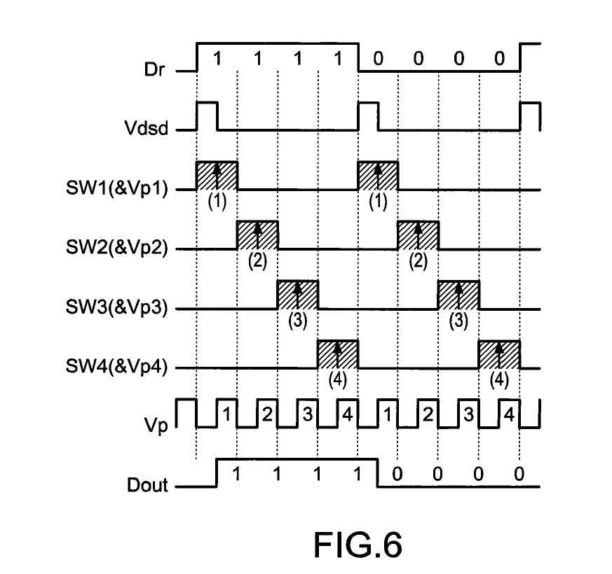

The circuit diagram, the truth table and the input/output waveform for the data switch detector 810 in FIG. 8 are similar to those shown in FIGS. 3a-3c. The data switch detector 810 comprises a half-period delay buffer 811 and an XOR gate 812. The two inputs of the half-period delay buffer 811 receive the input data signal Dr and the delay control signal, and the data switch detector 810 outputs an internal signal. The input data signal Dr and the internal signal are sent to two input ends of the XOR gate 812 to generate an output signal Vdsd. More particularly, output signal Vdsd with half-period duration is generated when data switching between binary 1 and binary 0 is present in the input data signal Dr. The output signal Vdsd is then sent to the switch control circuit 860, and then connected to the sub switch sets 831 and 832 for controlling switches therein.

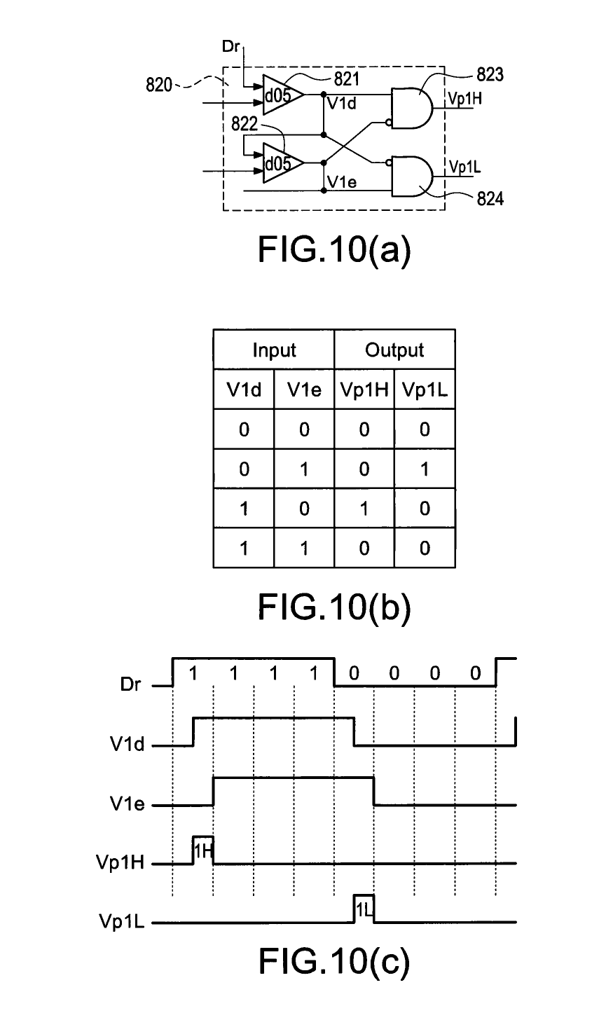

FIG. 10a shows the circuit diagram of the first set of logic circuit in the pulse generator 820, where the pulse generator 820 comprises a plurality sets of logic circuits and sequentially generates the first pulse signals Vp1H, Vp1L, . . . , to the n-th pulse signals VpnH, VpnL after receiving the input data signal Dr. The first set of logic circuit generates the first high-pass pulse signal Vp1H and the first low-pass pulse signal Vp1L, and then sends the signals to the first high-pass sub switch SW1H in the high-pass sub switch set 831, and the first low-pass sub switch SW1L in the low-pass sub switch set 832, respectively. As shown in FIG. 10c, the first high-pass pulse signal Vp1H is a pulse with high-period of logic high state with half-period delay when the input data signal Dr is changed from logic 0 to logic 1. The first high-pass pulse signal Vp1H is within the first period when the input data signal Dr is changed from logic 0 to logic 1. Similarly, the first low-pass pulse signal Vp1L is within the first period when the input data signal Dr is changed from logic 1 to logic 0.

Each set of logic circuit in the pulse generator 820 comprises two half-period delay buffers 821 and 822, and two AND gates 823, 824 (each AND gate has a non-inverted input end and an inverted input end). The first half-period delay buffer 821 is electrically connected to the non-inverted input end of the first AND gate 823 and the inverted input end of the second AND gate 824. The second half-period delay buffer 822 is electrically connected to the inverted input end of the first AND gate 823 and the non-inverted input end of the second AND gate 824. As shown in FIG. 10a, one input of the first half-period delay buffer 821 in the first set of logic circuit is electrically connected to the input data signal Dr, while one input of the second half-period delay buffer 822 is electrically connected to the output of the first half-period delay buffer 821. Moreover, the other inputs of the first half-period delay buffer 821 and the second half-period delay buffer 822 are connected to the delay control signals.

FIG. 10b shows the truth table for the first set of logic circuit in the pulse generator 820 shown in FIG. 10a, and the FIG. 10c shows the waveform for the first set of logic circuit in the pulse generator 820 shown in FIG. 10a. The input data signal Dr is delayed by the first half-period delay buffer 821 to form an internal signal V1d, and the internal signal V1d is delayed by the second half-period delay buffer 822 to form another internal signal V1e. The two internal signals V1d and V1e are sent to the two AND gates 823, 824 with truth table feature shown in FIG. 10b to output the first high-pass pulse signal Vp1H and the first low-pass pulse signal Vp1L, respectively. The first high-pass pulse signal Vp1H is logic high (“1”) with half-period and having half-period delay after the first period when the input data signal Dr is changed from logic 0 to logic 1. Similarly, the first low-pass pulse signal Vp1L is logic high (“1”) with half-period and having half-period the first period after the input data signal Dr is changed from logic 1 to logic 0.

In the second set of logic circuit in the pulse generator 820, the input of the first half-period delay buffer is electrically connected to the output of the second half-period delay buffer of previous set. The second set of logic circuit comprises a second half-period delay buffer and two AND gates as the first set of logic circuit to output the second high-pass pulse signal Vp2H and the second low-pass pulse signal Vp2L, respectively. In similar manner, the other sets of logic circuits can be formed to provide the high-pass pulse signals Vp3H-VpnH and the low-pass pulse signals Vp3L-VpnL, respectively.

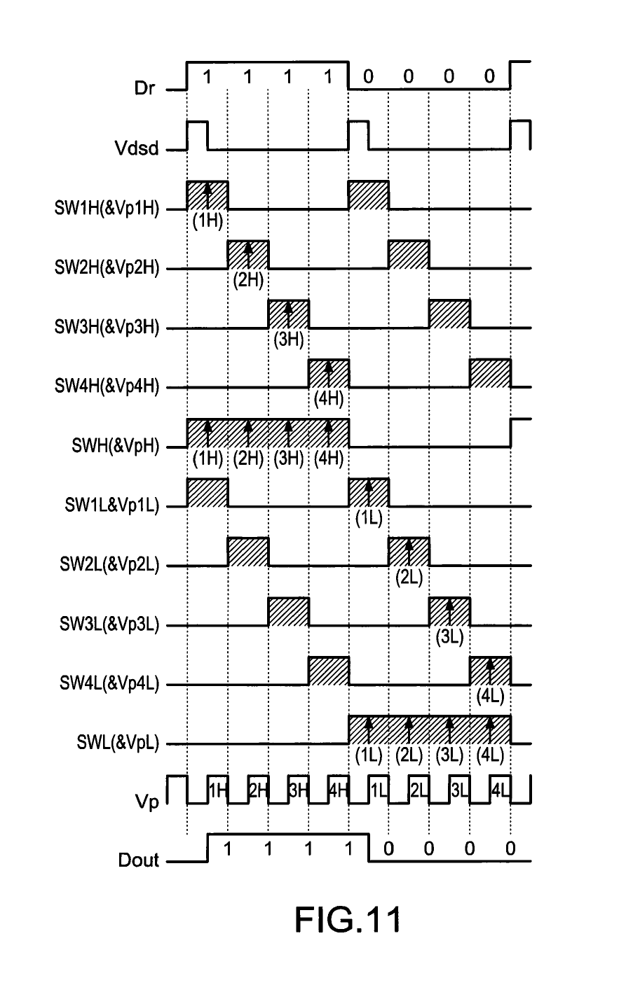

FIG. 11 shows the waveforms of the pulse signals and the switching status of switches, where all the pulse signals Vp1H˜VpnH, Vp1L˜VpnL, VpH, VpL and Vp are shown and the switching status of all switches SW1H˜SWnH, SW1L˜SWnL, SWH and SWL are shown. It should be noted only four sets of switches SW1H˜SW4H, SW1L˜SW4L, Vp1H˜Vp4H, Vp1L˜Vp4L are demonstrated in FIG. 11 for simplicity, and the implementation of the present invention can have other numbers of switches.

Taking the waveform for SW1H(&Vp1H) as example, the shaded pulse means that the high-pass first switch SW1H is on and the signal Vp1H is the input pulse signal for the high-pass first switch SW1H. The arrow “t” indicates a rising edge for the first high-pass pulse signal Vp1H. The number in the waveform means the ordinal number for the input data signal Dr. Taking the waveform for SWH(&VpH) as example, the shaded pulse means that the high-pass main switch SWH is on and the signal VpH is the input pulse signal for the high-pass main switch SWH.

The cooperation of the two sub switch sets 831 and 832 and the main switch set 840 will be explained with reference to FIG. 11. There are four successive logic high signals (with four-bit duration) in the beginning of the input data signal Dr, and the first to the fourth high pulse signals Vp1H˜Vp4H are sequentially generated. The first to fourth high pulse signals Vp1H˜Vp4H are sequentially processed by the first to fourth high-pass sub switches SW1H˜SW4H to form a high pulse signal VpH for the high pass main switch SWH, and the high pulse signal VpH functions as the final pulse signal Vp for the flip-flop 850. Namely, the final pulse signal Vp has four successive pulses in the four bit duration. The final pulse signal Vp is sent to the flip-flop 850 to trigger the input data signal Dr input to the flip-flop 850. Therefore, the flip-flop 850 can correctly output the data output signal Dout, where the output signal Dout is the final output for the input data recovery circuit of the present invention.

Similarly, when there are four successive logic low signals (with four-bit duration) appeared in the input data signal Dr, the first to the fourth low pulse signals Vp1L˜Vp4L are sequentially generated. The first to fourth low pulse signals Vp1L˜Vp4L are sequentially processed by the first to fourth low-pass sub switches SW1L˜SW4L to form a low pulse signal VpL for the low pass main switch SWL and the low pulse signal VpL functions as the final pulse signal Vp for the flip-flop 850. Namely, the final pulse signal Vp has four successive pulses in the four bit duration. The final pulse signal Vp is sent to the flip-flop 850 to trigger the input data signal Dr input to the flip-flop 850. Therefore, the flip-flop 850 can correctly output the data output signal Dout, where the output signal Dout is the final output for the input data recovery circuit of the present invention.

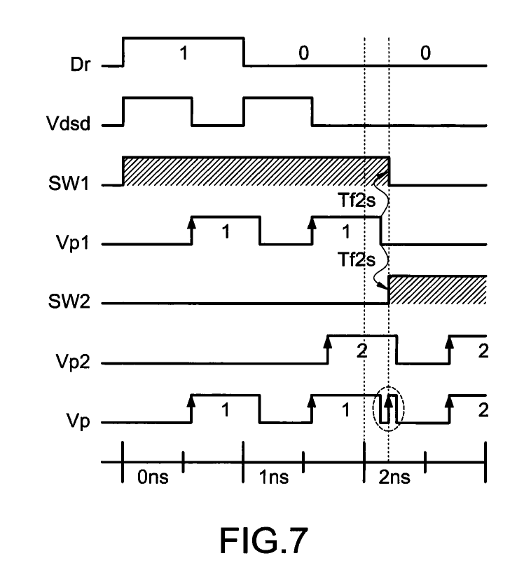

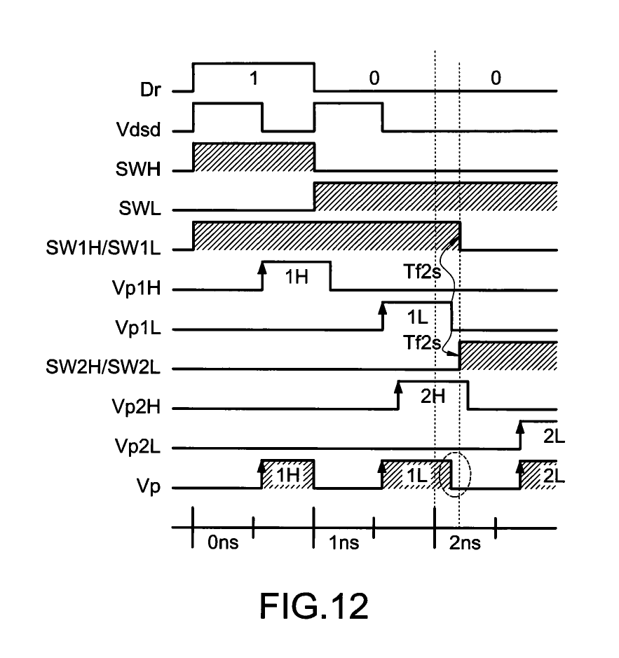

FIG. 12 shows the waveforms of some pulse signals according to the present, which is counterpart shown in FIG. 7, where unwanted pulse is not generated by the condition of ΔT>0 and over-short Tf2s (The delay time of pulse falling-edge to switch turn-on/turn-off). In FIG. 12, by the falling-edge triggering of the final pulse signal Vp (or the first low pulse signal Vp1L), the on status of the first sub switch SW1H/SW1L is switched to the on status of the second sub switch SW2H/SW2L. At this time, the low-pass main switch SWL is on and the high-pass main switch SWH is off. The tail of the second high-pass pulse signal Vp2H (corresponding to the previous Dr with logic 1) coincides with the second high-pass sub switch SW2H and does not coincide with the high-pass main switch SWH. Therefore, unwanted pulse is not generated and data error does not occur.

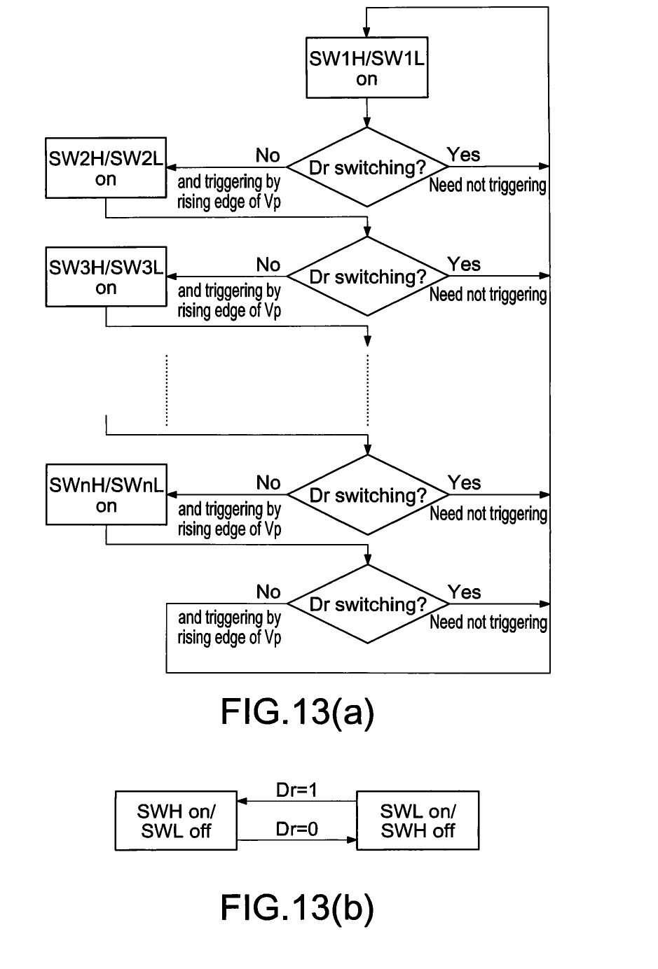

In the present invention, the falling edge of the final pulse signal Vp is used to trigger the two sub switch sets 831 and 832. Therefore, half-period delay is present between the rising edge of the final pulse signal Vp (which is used to trigger the input data signal Dr) and the triggering for the sub switch sets 831 and 832. The unwanted pulse does not occur even when ΔT>0 and Tf2s is short. FIG. 13a shows the flowchart for the switch control according to another embodiment of the present invention, which is similar to that in FIG. 9. In FIG. 13a, the triggering time for the sub switch sets 831 and 832 is advanced by half-period. When the rising edge of the final pulse signal Vp triggers the input data signal Dr, the rising edge also triggers the sub switch sets 831 and 832 to change the on status thereof. The parameter Tf2s becomes Tr2s (The delay time of pulse rising-edge to switch turn-on/turn-off). It is found that the pulse width (on time) of the final pulse signal Vp is T/2 when Tr2s is larger than T/2, and the pulse width (on time) of the final pulse signal Vp is Tr2s when Tr2s is smaller than T/2. In those situations, the pulse width (on time) of the final pulse signal Vp is sufficient (equal to T/2 or Tr2s), and unwanted pulse does not occur.

As shown in FIG. 13a, the switching of the sub switch sets 831 and 832 is advanced by half period and the input data recovery circuit can be used for higher-speed application. FIG. 13b shows the switching control of the main switch set according to another preferred embodiment of the present invention. It can be seen that the main switch set is directly controlled by the switching status of the input data signal Dr.

Although the present invention has been described with reference to the preferred embodiment thereof, it will be understood that the invention is not limited to the details thereof. Various substitutions and modifications have suggested in the foregoing description, and other will occur to those of ordinary skill in the art. Therefore, all such substitutions and modifications are intended to be embraced within the scope of the invention as defined in the appended claims.

What is claimed is:

1. An input data recovery circuit for asynchronous serial data transmission, the input data recovery circuit receiving an input data signal and a delay control signal and generating a data output signal, the input data recovery circuit comprising:
a data switch detector having two input ends for receiving the input data signal and the delay control signal, respectively, and an output end;
a pulse generator having two input ends for receiving the input data signal and the delay control signal, respectively, and a plurality of output ends for outputting pulses signals sequentially, wherein the pulses signals comprise high pulse signals and low pulse signals;
a high-pass sub switch set having a plurality of input ends, a high-pass output end and a plurality of control ends, wherein the plurality of input ends are electrically connected to the corresponding output ends of the pulse generator to receive the high pulse signals;
a low-pass sub switch set having a plurality of input ends, a low-pass output end and a plurality of control ends, wherein the plurality of input ends are electrically connected to the corresponding output ends of the pulse generator to receive the low pulse signals;
a main switch set comprising a high-pass main switch and a low-pass main switch, and having a high-pass input end, a low-pass input end, an output end, and two control ends, the high-pass input end electrically connected to the high-pass output end of the high-pass sub switch set to receive a high pulse signal from the high-pass sub switch set, the low-pass input end electrically connected to the low-pass output end of the low-pass sub switch set to receive a low pulse signal from the low-pass sub switch set, the main switch set sending a final pulse signal from the output end thereof;
a switch control circuit comprising a first input end, a second input end, a third input end and a plurality of output ends, the first input end electrically connected to the output end of the data switch detector, the second input end receiving the input data signal, the third input end electrically connected to the output end of the main switch set to receive the final pulse signal, the plurality of output ends respectively connected to the control ends of the main switch set and the control ends of the two sub switch sets; and
a flip-flop comprising a data input end for receiving the input data signal and a clock input end electrically connected to the output end of the main switch set to receive the final pulse signal, whereby the input data signal is triggered by the final pulse signal and the data output signal is generated from an output end of the flip-flop.

2. The input data recovery circuit in claim 1, wherein the data switch detector comprises
a half-period buffer having two input ends for respectively receiving the input data signal and the delay control signal, and an output end; and
an XOR gate having a first input end receiving the input data signal, a second input end electrically connected to the output end of the half-period buffer, and an output end electrically connected to the first input end of the switch control circuit.

3. The input data recovery circuit in claim 1, wherein the pulse generator comprises a plurality of sets of logic circuits, wherein each set of logic circuit comprises:
a first half-period delay buffer and a second half-period delay buffer connected in series and each having a first input end, a second input end and an output end, the first input end of the second half-period delay buffer electrically connected to the output end of the first half-period delay buffer, the second input ends of the first half-period delay buffer and the second half-period delay buffer receiving the delay buffer signal; and
a first AND gate and a second AND gate, each having a non-inverted input end and an inverted input end, the non-inverted input end of the first AND gate electrically connected to the output end of the first half-period delay buffer, the inverted input end of the first AND gate electrically connected to the output end of the second half-period delay buffer, the output end of the first AND gate outputting the high pulse signal, the inverted input end of the second AND gate electrically connected to the output end of the first half-period delay buffer, the non-inverted input end of the second AND gate electrically connected to the output end of the second half-period delay buffer, and the output end of the second AND gate outputting the low pulse signal;
wherein the first input end of the half-period delay buffer in the first set of logic circuit receives the input data signal, and the first input end of the first half-period delay buffer in each remaining set of logic circuit receives the output of the second half-period delay buffer in a previous set of logic circuit.

4. The input data recovery circuit in claim 1, wherein the high-pass sub switch set further comprises a plurality of high-pass sub switches, each of the high-pass sub switches having an input end, a control end and an output end, the input end of the high-pass sub switch connected to corresponding output end of the pulse generator to receive the high pulse signal, the control end of the high-pass sub switch connected to the switch control circuit, the output ends of all high-pass sub switches connected together to provide the high-pass output end, which is electrically connected to the high-pass input end of the main switch set to output the high pulse signal.

5. The input data recovery circuit in claim 4, wherein the low-pass sub switch set further comprises a plurality of low-pass sub switches, each of the low-pass sub switches having an input end, a control end and an output end, the input end of the low-pass sub switch connected to corresponding output end of the pulse generator to receive the low pulse signal, the control end of the low-pass sub switch connected to the switch control circuit, the output ends of all low-pass sub switches connected together to provide the low-pass output end, which is electrically connected to the low-pass input end of the main switch set to output the low pulse signal.

6. The input data recovery circuit in claim 1, wherein the switch control circuit controls the output of the data switch detector according to a falling edge of the final pulse signal, whereby the switches in the high-pass sub switch set, the low-pass sub switch set and the main switch set are turned on or off respectively.

7. The input data recovery circuit in claim 1, wherein the switch control circuit controls the output of the data switch detector according to a rising edge of the final pulse signal, whereby the switches in the high-pass sub switch set, the low-pass sub switch set and the main switch set are turned on or off respectively.
